(19) United States
(12) Patent Application Publication
(10) Pub. No.: US 2026/0314133 A1
(43) Pub. Date: Oct. 8, 2026

(54) OPTOELECTRONIC SEMICONDUCTOR DEVICE AND METHOD FOR PRODUCING AN OPTOELECTRONIC SEMICONDUCTOR DEVICE

(71) Applicant: ams-OSRAM International GmbH, Regensburg (DE)

(72) Inventors: Peter Blum, Donaustauf (DE); Michael Zitzlsperger, Regensburg (DE)

(21) Appl. No.: 19/483,967

(22) PCT Filed: May 2, 2024
(86) PCT No.: PCT/EP2024/062062

§ 371 Date: Nov. 12, 2025

(30) Foreign Application Priority Data
May 17, 2023 (DE) 102023113060.9

(51) Int. Cl. H10H 20/856; H10H 20/01

(52) U.S. Cl. CPC H10H 20/856; H10H 20/0363

(57) ABSTRACT

In an embodiment an optoelectronic semiconductor device includes an optoelectronic semiconductor chip arranged in at least one cavity of a housing and configured to emit electromagnetic radiation and an insert, wherein the cavity comprises at least one side surface at least partially laterally surrounding the optoelectronic semiconductor chip, wherein the insert is arranged between the optoelectronic semiconductor chip and the side surface at a distance from the optoelectronic semiconductor chip, and wherein the distance between the insert and the optoelectronic semiconductor chip is at most 250 μm.

### CROSS-REFERENCE TO RELATED APPLICATIONS

This patent application is a national phase filing under section 371 of PCT/EP2024/062062, filed May 2, 2024, which claims the priority of German patent application no. 102023113060.9, filed May 17, 2023, each of which is incorporated herein by reference in its entirety.

### TECHNICAL FIELD

An optoelectronic semiconductor device is specified. Furthermore, a method for producing an optoelectronic semiconductor device is specified.

### SUMMARY

Embodiments provide an optoelectronic semiconductor device having a high contrast. Further embodiments provide a method for producing such an optoelectronic semiconductor device.

According to at least one embodiment of the optoelectronic semiconductor device, the optoelectronic semiconductor device comprises an optoelectronic semiconductor chip which is configured to emit electromagnetic radiation. For example, the optoelectronic semiconductor chip is a light-emitting diode or a laser diode. In the latter case the optoelectronic semiconductor chip may be a vertical-cavity surface-emitting laser, VCSEL for short.

The optoelectronic semiconductor chip comprises a semiconductor layer sequence including an active zone. During operation, electromagnetic radiation is produced in the active zone. For example, electromagnetic radiation in the blue or green or red spectral range or in the UV range or in the IR range is generated in the active zone during intended operation. In particular, it is possible that electromagnetic radiation in a wavelength range between and including the IR range and the UV range is generated in the active zone.

According to at least one embodiment, the optoelectronic semiconductor device comprises a housing with at least one cavity. Preferably the optoelectronic semiconductor chip is arranged in the at least one cavity of the housing. In particular, the cavity is a recess of the housing. It is possible that a plurality of optoelectronic semiconductor chips is arranged in the housing. This means that, if in the following reference is made to the “optoelectronic semiconductor chip”, in particular also “a plurality of semiconductor chips” is included if appropriate.

The housing is at least partially formed with an electrically insulating material. For example, the housing comprises a mold material such as a polymer and/or a resin.

According to at least one embodiment, the cavity comprises at least one side surface at least partially laterally surrounding the optoelectronic semiconductor chip. Here and in the following, a lateral direction is a direction parallel to a main extension plane of the optoelectronic semiconductor chip, in particular of the active zone of the optoelectronic semiconductor chip. In particular, the main extension plane of the optoelectronic semiconductor chip is parallel to a bottom of the cavity. Preferably, the optoelectronic semiconductor chip is arranged on the bottom of the cavity.

Preferably, the side surface comprises an angle with respect to the main extension plane of the optoelectronic semiconductor chip. In particular, the angle is an obtuse angle. That is, the sensor face extends transverse to the optoelectronic semiconductor chip and/or the bottom of the cavity.

According to at least one embodiment, the optoelectronic semiconductor device further comprises an insert. In particular, the insert is arranged between the optoelectronic semiconductor chip and the side surface of the cavity at a distance from the optoelectronic semiconductor chip. For example, the insert is in contact, in particular in direct contact, with the side surface. It is possible that the insert is in contact or direct contact with all side surfaces of the cavity. For example, the insert is in contact or direct contact with the bottom of the cavity. Alternatively, there is a gap between the insert and the bottom of the cavity. In particular, the insert forms a frame at least partially surrounding the optoelectronic semiconductor chip in lateral directions.

The distance is, for example, an average distance between the insert and the optoelectronic semiconductor chip. Preferably, the distance is a minimum distance between the insert and the optoelectronic semiconductor chip. In particular, the distance is measured along a straight line parallel to a main extension plane of the semiconductor chip.

In particular, the semiconductor chip and the insert do not touch at any point. That is, the insert is preferably arranged adjacent to the semiconductor chip without contacting or direct contacting the semiconductor chip at any point.

For example, a side of the insert facing the semiconductor chip is arranged at a distance from the semiconductor chip. In other words, a surface of the semiconductor chip facing the insert or preferably all outer surfaces of the semiconductor chip are free of the insert, wherein “free” in this context in particular means that there is no direct contact between the semiconductor chip and the insert.

The insert is preferably at least partially arranged in an intermediate space between the side surfaces of the housing and the semiconductor chip defined by any straight line in lateral direction between the semiconductor chip and the side walls of the housing. That is, for example, the intermediate space is limited in a direction normal to the main extension plane of the semiconductor chip by a cover surface or emission surface of the semiconductor chip and a bottom surface or mounting surface of the semiconductor chip. Hence, the intermediate space preferably directly adjoins the semiconductor chip on a side facing the side surface of the housing. From this side of the semiconductor chip the intermediate space preferably extends in a straight in the lateral direction to the side surface of the housing.

A space between the optoelectronic semiconductor chip and the insert and/or the side surface of the cavity is preferably filled with a casting. For example, the casting is used to fill up the cavity. The casting comprises in particular a resin, such as an epoxy, or a silicone. For example, the casting comprises a matrix material which is filled with a filler material. In particular, the filler material may be a reflecting or absorbing material for radiation emitted by the optoelectronic semiconductor chip. For example, the matrix material comprises a resin, an epoxy and/or a silicone. The filler material may comprise TiO₂ or ZrO₂, for example, TiO₂ and/or ZrO₂ particles.

Preferably, the insert comprises a different material than the housing. In particular, the insert is formed with a material comprising a particularly large absorption coefficient for radiation emitted by the optoelectronic semiconductor chip. For example, the absorption coefficient of the insert is larger than 80% or 90% or 95%. The insert comprises, for example, a polysiloxane, a metal and/or a glass. Advantageously, the material of the insert can be chosen independently of the material of the housing.

In at least one embodiment of the optoelectronic semiconductor device, the optoelectronic semiconductor device comprises an insert and an optoelectronic semiconductor chip configured to emit electromagnetic radiation and arranged in at least one cavity of a housing. The cavity comprises at least one side surface at least partially laterally surrounding the optoelectronic semiconductor chip. The insert is arranged between the optoelectronic semiconductor chip and the side surface of the cavity at a distance from the optoelectronic semiconductor chip.

The optoelectronic semiconductor device described here is based, inter alia, on the following technical considerations. In some applications, for example automotive headlights, lighting devices comprising optoelectronic semiconductor devices for light emission are desired to be free of apertures. This requires in particular a high contrast between emission surfaces of the optoelectronic semiconductor device and other parts of the optoelectronic semiconductor device. Typical requirements are that in a distance of, for example, at most 250 um the contrast comprises a predefined value.

Usually, the emission surface is arranged closely to an edge of the device, in order to obtain the desired contrast. However, such an arrangement is disadvantageous regarding robustness and handling of the device and with respect to performance since light may leak laterally out of the device thus not usable an application. Alternatively, a small cavity of the housing with absorbing side surfaces is used. This, however, requires a precise forming of the housing and/or the cavity, which is expensive in production. Furthermore, a lifespan of the semiconductor device is limited due to delamination. It is also possible to provide a dark, i.e. black, coating as a cover layer of the housing in order to increase contrast. This may not prevent a lateral leakage of radiation.

The optoelectronic semiconductor device described here is based, inter alia, on the idea of providing an insert, by which lateral emission through the housing is reduced or avoided. Thereby, the material of the housing is shielded and protected against radiation of the optoelectronic semiconductor chip. In particular, a material of the insert can be chosen to be better absorbing and/or reflecting and more radiation resistant than the material of the housing. Advantageously, the material of the insert can be chosen independently of the material of the housing. This enables a high contrast of the optoelectronic semiconductor device, in particular within a predefined distance to an emission surface of the optoelectronic semiconductor chip.

Furthermore, a particularly high contrast can be achieved by using the insert. The contrast is, for example, 1:250. In particular, the contrast is determined by the ratio of a maximal brightness of the housing and/or the insert and an average brightness of the emission surface. Advantageously, this contrast is reached at a distance of smaller than 250 μm by using the insert.

During production of the optoelectronic semiconductor device, a step of arranging the insert is preferably carried out after the optoelectronic semiconductor chip is arranged in the cavity, which allows the usage of a comparably large cavity. Arranging the optoelectronic semiconductor chip is thus facilitated. In particular, also other geometrical properties of the cavity such as fillets and tilting angle of the side surfaces can be chosen in order to facilitate the arrangement of the optoelectronic semiconductor chip.

According to at least one embodiment, the insert is impermeable to radiation emitted by the optoelectronic semiconductor chip. In particular, at least 80% or at least 90% or at least 95% of the radiation striking the insert are absorbed/reflected. For example, a transmission coefficient of the insert is smaller than 20% or smaller than 10% or smaller than 5%.

Furthermore, the housing is shielded against radiation of the optoelectronic semiconductor chip. As a further advantage a high contrast can be achieved with such an insert. The contrast is, for example, 1:250.

According to at least one embodiment, the distance between the insert and the optoelectronic semiconductor chip is at most 250 μm. That is, the insert is arranged close to the optoelectronic semiconductor chip. Advantageously, a high contrast may be achieved at a comparably small distance by using the insert.

According to at least one embodiment, a first side of the insert facing away from the optoelectronic semiconductor chip comprises a contour that matches a contour of the side surface of the cavity. This allows the insert to be properly attached to the housing.

According to at least one embodiment, a second side of the insert facing the optoelectronic semiconductor chip comprises an undercut. The undercut is in particular defined by a transverse second side of the insert that is transverse to the main extension plane of the optoelectronic semiconductor chip, i.e. the active zone of the optoelectronic semiconductor chip, and/or a bottom of the cavity. The transverse second side surface comprises an angle with respect to the main extension plane of the optoelectronic semiconductor chip. In particular, the angle is an acute angle. For example, the transverse second side surface is tilted in the opposite direction as the side surface of the cavity. In particular, such an undercut is not possible in a housing produced by standard techniques.

By the undercut, the distance, in particular a minimum distance, between the insert and the optoelectronic semiconductor chip, may be decreased. In particular, the distance may be increased in a plane in the vicinity of and parallel to an emission surface of the optoelectronic semiconductor chip. Here and in the following, the emission surface is a surface of the optoelectronic semiconductor chip from which at least 70% or at least 80% or at least 90% of the radiation produced in the active zone during operation is emitted. Preferably, the emission surface is parallel to the main extension plane of the semiconductor chip and/or the active zone of the semiconductor chip.

According to at least one embodiment, a material of the insert is different from a material of the housing. For example, the insert comprises at least one of the following materials: a metal, a glass, a polysiloxane. In particular, the material of the insert is in principle freely variable. This means that the material of the insert can be chosen independently of the material of the housing. This allows the insert to be chosen with a material showing particularly good properties in order to achieve a large contrast.

According to at least one embodiment, the cover surface of the insert is at least as high as an emission surface of the optoelectronic semiconductor chip. The height is measured in particular perpendicular to the bottom of the cavity. In particular, the cover surface is an outer surface of the insert facing away from the bottom of the cavity.

In particular, the cover surface of the insert and the emission surface may lie in a common plane, that is, for example, perpendicular to the semiconductor chip, the active zone of the semiconductor chip and/or the bottom of the cavity. Alternatively, the cover surface of the insert may be in a plane that is above the emission surface. “Above” means here that the plane of the cover surface of the insert has a bigger distance to the bottom of the cavity than the emission surface.

According to at least one embodiment, the optoelectronic semiconductor chip comprises a phosphor layer forming the emission surface. The phosphor layer comprises at least one phosphor configured to at least partially convert radiation generated in the active zone during operation in converted radiation having a longer wavelength. The phosphor layer comprises for example a matrix in which phosphor particles are arranged. For example, the matrix is formed with a ceramic material. In this case, the phosphor layer is formed with a ceramic plate that is attached to the optoelectronic semiconductor chip.

In particular, in intended operation, the optoelectronic semiconductor device emits mixed radiation comprising radiation generated in the active zone and converted radiation. For example, if the phosphor is a yellow phosphor such as a YAG phosphor and the radiation generated in the active zone is in the blue wavelength range, the mixed radiation is preferably white light. Advantageously, via the phosphor layer a color location of the radiation emitted by the optoelectronic semiconductor device can be set.

According to at least one embodiment, the insert at least partially covers a cover surface of the housing. The cover surface of the housing is in particular a surface of the housing facing away from the bottom of the cavity. Preferably, a side of the insert facing the cover surface of the housing matches the shape of the cover surface of the housing. Hence, an attachment of the insert on the cover surface of the housing may be particularly robust. By arranging the insert at least partially at the cover surface of the housing, the contrast may be increased in regions of the housing.

According to at least one embodiment, the optoelectronic semiconductor device further comprises at least one lead frame with two parts configured to supply the optoelectronic semiconductor chip with current. The optoelectronic semiconductor chip is arranged on a first part of the lead frame. A bond wire electrically conductively connects the optoelectronic semiconductor chip with a second part of the lead frame. Preferably, the insert at least partially covers the bond wire in a top view. For example, the lead frame forms at least part of the bottom of the cavity. The lead frame is, for example, formed with at least one metal such as copper.

The bond wire may be electrically conductively connected to the optoelectronic semiconductor chip and/or the second part of the lead frame by means of a contact structure. For example, the first part of the lead frame forms an anode for the optoelectronic semiconductor chip and the second part of the lead frame forms a cathode for the optoelectronic semiconductor chip or vice versa. The bond wire is preferably protected by the insert. For example, this allows or facilitates a bulk handling of the optoelectronic semiconductor device. Furthermore, a high contrast may be achieved in the region of the bond wire.

According to at least one embodiment, the optoelectronic semiconductor device comprises at least one aperture which is arranged on the insert. Preferably, the aperture is arranged at or on the cover surface of the insert. By the aperture a high contrast at a particularly small distance may be achieved.

According to at least one embodiment, the optoelectronic semiconductor chip is a micro-LED.

As a broad definition, a micro-LED could be seen as any light emitting diode (LED) generally not a laser—with a particularly small size.

As a rule—and this is a very important criterion in addition to size-a growth substrate is removed from micro-LEDs, so that typical heights of such micro-LEDs are in the range of 1.5 μm to 10 μm, for example.

In principle, a micro-LED does not necessarily have to have a rectangular radiation emission surface. Generally, for example, an LED could have a radiation emission surface in which, in a top view of layers of the semiconductor layer sequence, any lateral extent of the radiation emission surface is less than or equal to 100 μm or less than or equal to 70 μm.

For example, in the case of rectangular micro-LEDs, an edge length—especially in a top view of the layers of the semiconductor layer sequence-smaller than or equal to 70 μm or smaller than or equal to 50 μm is often cited as a criterion.

Mostly, such micro-LEDs are provided on wafers with—for the μLED non-destructively—detachable holding structures.

At present, micro-LEDs are mainly used in displays. The micro-LEDs form pixels or subpixels and emit light of a defined color. Small pixel size and a high density with close distances make micro-LEDs suitable, among others, for small monolithic displays for AR applications, especially data glasses. In addition, other applications are being developed, in particular regarding the use in data communication or pixelated lighting applications or automotive headlights.

Different ways of spelling micro-LED, e.g. μLED, μ-LED, uLED, u-LED or micro light emitting diode can be found in the relevant literature.

Furthermore, a lighting device is specified. In particular, the lighting device comprises at least one optoelectronic semiconductor device described here. That is, all features disclosed for the optoelectronic semiconductor device are also disclosed for the lighting device and vice versa.

Preferably the lighting device is free of an aperture.

Furthermore, a method for producing an optoelectronic semiconductor device is specified. In particular, the optoelectronic semiconductor device described here may be produced by the method. That is, all features disclosed for the optoelectronic semiconductor device are also disclosed for the method and vice versa.

According to at least one embodiment of the method for producing an optoelectronic semiconductor device, the method comprises a step of providing a housing with a plurality of cavities. The housing is formed, for example, by injection molding. For example, the housing is produced by molding a lead frame.

According to at least one embodiment of the method, in another method step an optoelectronic semiconductor chip is arranged in each cavity such that side surfaces of the respective cavity at least partially surround the optoelectronic semiconductor chip. For example, the optoelectronic semiconductor chip is placed in the cavity by a pick-and-place process.

According to at least one embodiment of the method, the method comprises arranging at least one insert between the optoelectronic semiconductor chip and the side surface of the cavity at a distance from the optoelectronic semiconductor chip, particularly in each cavity. It is possible that the insert extends over a plurality of cavities or all cavities. This means that the number of inserts may be smaller than the number of cavities. For example, an optoelectronic semiconductor device is finished by arranging the insert.

Advantageously, the cavity may be formed with a comparably large opening. As a particular consequence, process steps have not to be varied or only slightly adapted to different applications. This applies in particular to the injection molding of the housing. That is, the same injection molding process may be used for a plurality of applications of the optoelectronic semiconductor device. This is in particular possible since optical properties such as the contrast are essentially determined by the insert and especially not the housing. Hence, if the optoelectronic semiconductor device is used in different applications, preferably essentially only the insert has to be adapted accordingly.

According to at least one embodiment of the method, the method comprises separating the housing along separation lines, such that a plurality of optoelectronic semiconductor devices is formed. In particular, each optoelectronic semiconductor device may comprise one cavity and one optoelectronic semiconductor chip.

According to at least one embodiment of the method, the step of arranging the insert is carried out after arranging the optoelectronic semiconductor chip. Preferably, the step of arranging the insert is carried out after the optoelectronic semiconductor chip is electrically contacted by a bond wire. Advantageously, this order of steps facilitates the arrangement of the optoelectronic semiconductor chip and/or the arrangement of the bond wire since the whole cavity is accessible for placing the optoelectronic semiconductor chip and/or the bond wire.

According to at least one embodiment of the method, each cavity has a lateral extent of at least 250 μm. The lateral extent is in particular an extent in a lateral direction. For example, the lateral extent of at least 250 μm is a maximal lateral extent of the cavity. With such a comparably large cavity, the arrangement of the optoelectronic semiconductor chip and/or the insert is particularly easy to be carried out.

According to at least one embodiment of the method, the insert is arranged in contact with the side surface of the cavity and the insert aligns itself at the side surface. For example, a first side of the insert facing the side surface matches the shape of the side surface. That is, the first side of the insert comprises a contour which matches a contour of the side surface of the cavity. Consequently, if the insert is slightly misaligned with respect to the side surface, the insert will move essentially to its correct position due to the matching contours. As a result of the self-alignment of the insert, the insert may be arranged in the cavity with a higher tolerance.

### BRIEF DESCRIPTION OF THE DRAWINGS

Further advantages and advantageous embodiments and further developments of the optoelectronic semiconductor device and the method for producing an optoelectronic semicondcutor device will become apparent from the following exemplary embodiments shown in connection with schematic drawings. Identical elements, elements of the same kind or elements having the same effect are provided with the same reference signs in the figures. The figures and the proportions of the elements shown in the figures are not to be regarded as true to scale. Rather, individual elements may be shown exaggeratedly large for better representability and/or for better comprehensibility.

In the figures:

FIGS. 1 to 6 show schematic sectional views of an optoelectronic semiconductor device described here according to exemplary embodiments; and

FIGS. 7 to 9 show schematic sectional views of positions in a method for producing an optoelectronic semiconductor device described here according to an exemplary embodiment.

### DETAILED DESCRIPTION OF ILLUSTRATIVE EMBODIMENTS

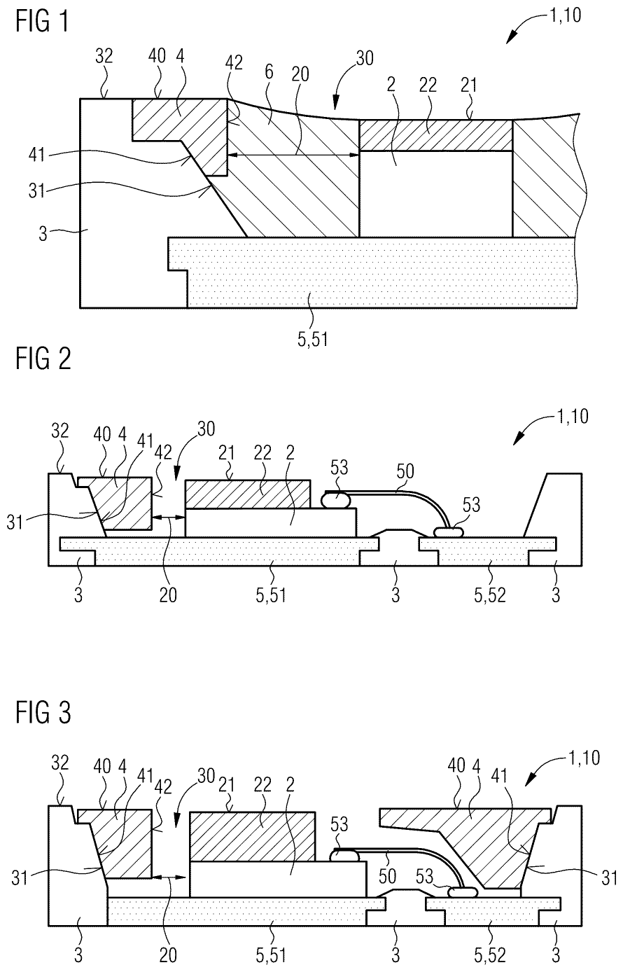

In FIGS. 1 to 9 a sectional plane for the sectional view is perpendicular to a main extension plane of an optoelectronic semiconductor chip 2 of the optoelectronic semiconductor device 1.

FIGS. 1 and 2 show a schematic sectional view of an optoelectronic semiconductor device 1 according to an exemplary embodiment. The optoelectronic semiconductor device 1 according to FIGS. 1 and 2 comprises an optoelectronic semiconductor chip 2. The optoelectronic semiconductor chip 2 comprises an active zone configured for generating electromagnetic radiation. For example, radiation in the blue wavelength range is generated in the active zone during intended operation. The optoelectronic semiconductor chip 2 further comprises a phosphor layer 22 and an emission surface 21. The phosphor layer 22 is configured to convert at least part of the electromagnetic radiation generated in the active zone to a converted radiation having a longer wavelength. In particular, mixed radiation comprising the electromagnetic radiation generated in the active zone and converted radiation is emitted by the optoelectronic semiconductor chip 2 via the emission surface 21. The mixed light is, for example, white light.

The optoelectronic semiconductor chip 2 is arranged in a cavity 30 of the housing 3. The cavity 30 is a recess of the housing 3. The housing 3 is at least partially formed with an electrically insulating material. The housing 3 comprises a mold material such as a polymer or a resin and is preferably produced by injection molding.

Furthermore, the optoelectronic semiconductor device 1 comprises a lead frame 5, which may be part of the housing 3. The lead frame 5 comprises a fist part 51 and a second part 52. The optoelectronic semiconductor chip 2 is arranged on the first part 51. The optoelectronic semiconductor chip 2 is electrically conductively connected to the second part 52 by a bond wire 50. The bond wire 50 is electrically conductively connected to a contact structure 53 of the optoelectronic semiconductor chip 2 and to a contact structure 53 of the second part 52 of the lead frame 5 (compare FIG. 2). The lead frame 5 is configured to supply the optoelectronic semiconductor chip 2 with current. For example, the first part 51 forms an anode for the optoelectronic semiconductor chip 2 and the second part 52 forms a cathode for the optoelectronic semiconductor chip 2. The lead frame 5 is preferably formed with copper.

The optoelectronic semiconductor device 1 further comprises an insert 4. The insert 4 is arranged at a distance 20 from the optoelectronic semiconductor chip 2. In a direction away from the lead frame 5 the insert 4 projects beyond the optoelectronic semiconductor chip 2. That is, a cover surface 40 of the insert 4 facing away from the lead frame 5 has a greater height than the emission surface 21 of the optoelectronic semiconductor chip 2. A material of the insert 4 may be chosen independently of a material of the housing 3. For example, the material of the insert 4 is impermeable to radiation emitted by the optoelectronic semiconductor chip 2 during operation and is configured to at least partially shield the housing 3 against the radiation emitted by the optoelectronic semiconductor chip 2. An absorption coefficient of the insert 4 is, for example, at least 80% or at least 90% or at least 95%. In turn, a transmission coefficient of the insert 4 is, for example, at most 50% or at most 10% or at most 5%. The insert 4 comprises, for example, at least one of the following materials: polysiloxane, glass, metal.

The distance 20 between the insert 4 and the optoelectronic semiconductor chip 2 is at most 250 μm. It is therefore possible to achieve a high contrast at a distance smaller than 250 μm by the insert 4. The contrast is, for example, at least 1:250. Furthermore, the housing 3 may be shielded against radiation emitted by the optoelectronic semiconductor chip 2. Additionally, a leakage of radiation in lateral directions is reduced or prevented by the insert 4.

A space between the optoelectronic semiconductor chip 2 and the insert 4 is filled with a casting 6. The casting 6 comprises, for example, an epoxy or a silicone. The casting 6 may additionally be filled with a reflecting or absorbing material such as TiO₂ and/or ZrO₂. In particular, the insert 4 and the optoelectronic semiconductor chip 2 are fixedly arranged in the cavity 30 by means of the casting 6. In FIGS. 2 to 9 representation of the casting 6 is omitted for clarity reasons.

The cavity 30 comprises side surfaces 31. The side surfaces 31 comprise an obtuse angle with respect to the lead frame 5. The side surfaces 31 at least partially surround the optoelectronic semiconductor chip 2 in lateral directions. A first side 41 of the insert 4 facing the side surface 31 comprises a contour which matches a contour of the side surface 31. Thereby, a gap between the side surface 31 and the insert 4 is prevented.

The optoelectronic semiconductor device 1 of the exemplary embodiment may be part of a lighting device 10. The device 10 is free of an aperture 7. That is, all other optoelectronic semiconductor devices 1 according to the exemplary embodiments which are free of an aperture 7 may also form a lighting device 10.

In contrast to the exemplary embodiment of FIGS. 1 and 2, the optoelectronic semiconductor device according to FIG. 3 comprises a further insert 4 arranged in the region of the second part 52 of the lead frame 5. The insert 4 and the further insert 4 may be connected to one another and formed in one piece. In this case, the insert 4 forms a frame that at least partially surrounds the optoelectronic semiconductor chip 2 in lateral directions.

In the region of the second part 52 of the lead frame 5, the insert covers the bond wire 50 at least partially in a top view of the cavity 30. Thereby, the bond wire 50 is protected by the insert 4.

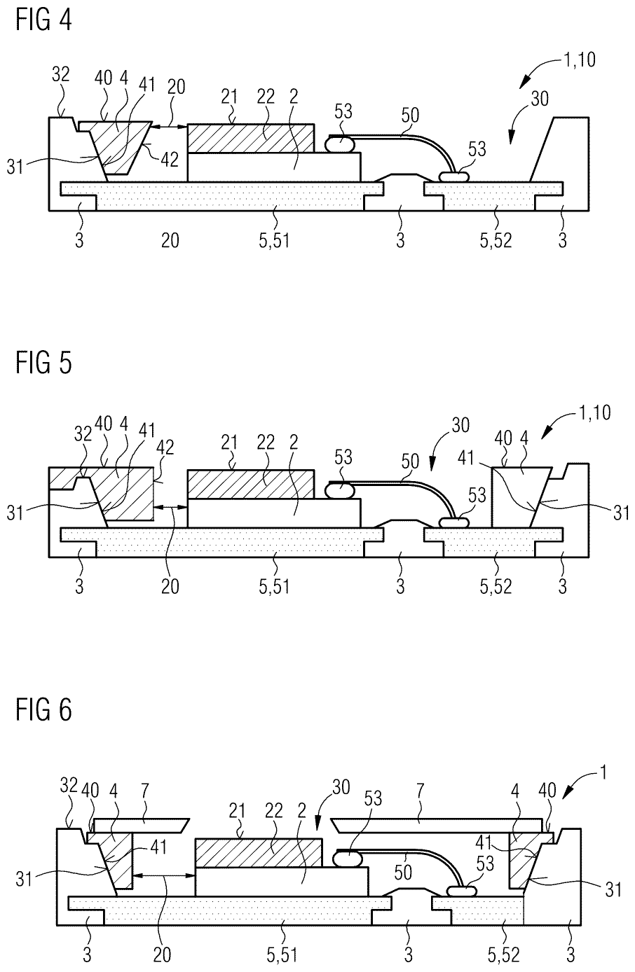

In contrast to the exemplary embodiment of FIG. 2, in the optoelectronic semiconductor device 1 according to FIG. 4, the insert 4 comprises an undercut. That is, a second surface 42 of the insert 4 facing the optoelectronic semiconductor chip 2 comprises an acute angle with respect to the lead frame 5. Such an undercut cannot be produced for the housing 3 with standard production techniques. By the undercut, the distance 20, which is in particular a minimal distance between the insert 4 and the optoelectronic semiconductor chip 2, may be further decreased.

In contrast to the previous exemplary embodiments, the insert 4 of the optoelectronic semiconductor device 1 according to FIG. 5 in the region of the first part 51 of the lead frame 5 at least partially covers a cover layer 32 of the housing 3. That is, in a top view of the cavity 30, the cover layer and the side surface of the housing 3 are covered by the insert 4. Therefore, a contrast in the region of the housing may be increased.

Furthermore, the optoelectronic semiconductor device according to FIG. 5 comprises an insert in a region of the second part of the lead frame 5, which is in contact, in particular direct contact, with the lead frame 5. This allows the insert 4 to be particularly easily arranged in the cavity 30. In particular all inserts 4 of the other exemplary embodiments may be in direct contact with the lead frame 5.

The exemplary embodiment of the optoelectronic semiconductor device 1 according to FIG. 6 further comprises an aperture 7 in contrast to the previously described exemplary embodiments. The aperture 7 is arranged on the insert 4. That is, the aperture 7 is in direct contact with the insert 4. By the aperture 7, a particularly high contrast may be achieved at a particularly small distance from the optoelectronic semiconductor chip 2. Preferably, the aperture 7 is formed with a material impermeable to radiation emitted by the optoelectronic semiconductor chip 2.

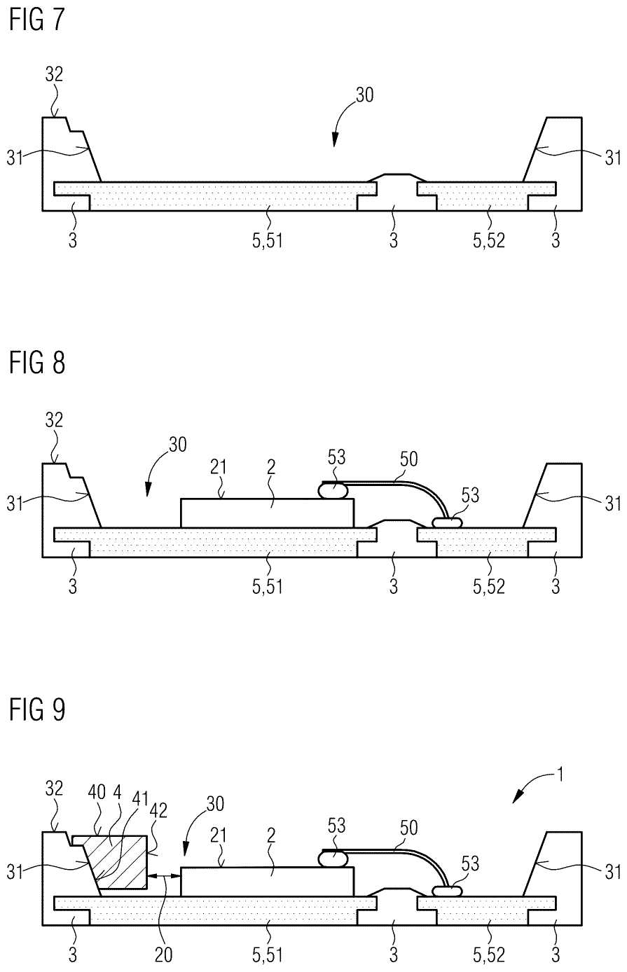

In the method according to FIGS. 7 to 9, in a first step a housing 3 comprising a cavity 30 is provided (FIG. 7). The housing 3 further comprises a lead frame 5 with a first part 51 and a second part 52. The cavity 30 comprises a lateral extent of, for example, at least 250 μm, facilitating subsequent method steps, where further entities are arranged in the cavity 30. In particular, the housing 3 and the cavity 30 and the lead frame 5 have features corresponding to those described in connection with the previously described exemplary embodiments.

In a further method step an optoelectronic semiconductor chip 2 is arranged in the cavity 30. The optoelectronic semiconductor chip 2 is arranged on the first part 51 of the lead frame 5. The first part 51 serves, for example, as an anode for the optoelectronic semiconductor chip 2. The optoelectronic semiconductor chip 2 is electrically conductively connected to the second part 52 of the lead frame 5 by a bond wire 50. The bond wire 50 is connected to both the second part 52 and the optoelectronic semiconductor chip 2 by a contact structure 53. The second part 52 serves, for example, as a cathode for the optoelectronic semiconductor chip 2. In contrast to the previously described exemplary embodiments, the optoelectronic semiconductor chip 2 does not comprise a phosphor layer 22. In other aspects the optoelectronic semiconductor chip 2 comprises the same features as the optoelectronic semiconductor chip 2 of the previously described exemplary embodiments.

In a further method step an insert 4 is arranged at a distance 20 from the optoelectronic semiconductor chip 2. The insert 4 is in direct contact with the housing 3 at a side surface 31. The side surface 31 and a first side 41 of the insert 4 facing away from the optoelectronic semiconductor chip 2 comprise a similar contour. Optionally a casting 6 (not shown) may be applied in the cavity 30 in a space between the optoelectronic semiconductor chip 2 and the insert 4 and/or the side surfaces 31 (compare FIG. 1). In particular, by arranging the insert 4 an optoelectronic semiconductor device 1 is finished. The insert 4 in particular has the same features as the insert 4 of the exemplary embodiment of FIG. 2.

The invention is not restricted to the exemplary embodiments by the description on the basis of said exemplary embodiments. Rather, the invention encompasses any new feature and also any combination of features which in particular comprises any combination of features in the patent claims and any combination of features in the exemplary embodiments, even if this feature or this combination itself is not explicitly specified in the patent claims or exemplary embodiments.

1.-17. (canceled)

18. An optoelectronic semiconductor device comprising:
an optoelectronic semiconductor chip arranged in at least one cavity of a housing and configured to emit electromagnetic radiation; and
an insert,
wherein the cavity comprises at least one side surface at least partially laterally surrounding the optoelectronic semiconductor chip,
wherein the insert is arranged between the optoelectronic semiconductor chip and the side surface at a distance from the optoelectronic semiconductor chip, and
wherein the distance between the insert and the optoelectronic semiconductor chip is at most 250 μm.

19. The optoelectronic semiconductor device according to claim 18, wherein the insert is impermeable to the radiation.

20. The optoelectronic semiconductor device according to claim 18, wherein a first side of the insert facing away from the optoelectronic semiconductor chip comprises a contour that matches a contour of the side surface of the cavity.

21. The optoelectronic semiconductor device according to claim 18, wherein at a second side facing the optoelectronic semiconductor chip the insert comprises an undercut.

22. The optoelectronic semiconductor device according to claim 18, wherein the insert comprises at least one of the following materials: a metal, a glass, or a polysiloxane.

23. The optoelectronic semiconductor device according to claim 18, wherein a cover surface of the insert is at least as high as an emission surface of the optoelectronic semiconductor chip.

24. The optoelectronic semiconductor device according to claim 23, wherein the optoelectronic semiconductor chip comprises a phosphor layer forming the emission surface.

25. The optoelectronic semiconductor device according to claim 18, where the insert at least partially covers a cover surface of the housing.

26. The optoelectronic semiconductor device according to claim 18, further comprising:
at least one lead frame with two parts configured to supply the optoelectronic semiconductor chip with current,
wherein the optoelectronic semiconductor chip is arranged on a first part of the lead frame,
wherein a bond wire electrically conductively connects the optoelectronic semiconductor chip with a second part of the lead frame, and
wherein the insert at least partially covers the bond wire in a top view.

27. The optoelectronic semiconductor device according to claim 18, further comprising at least one aperture arranged at a cover surface of the insert.

28. The optoelectronic semiconductor device according to claim 18, wherein the optoelectronic semiconductor chip is a micro-LED.

29. A lighting device comprising:
at least one optoelectronic semiconductor device according to claim 18,
wherein the lighting device is free of an aperture.

30. A method for producing an optoelectronic semiconductor device, the method comprising:
providing a housing with a plurality of cavities;
arranging an optoelectronic semiconductor chip in each cavity such that side surfaces of a respective cavity at least partially surround the optoelectronic semiconductor chip; and
arranging at least one insert between the optoelectronic semiconductor chip and the side surface of a respective cavity at a distance from the optoelectronic semiconductor chip such that the distance between the insert and the optoelectronic semiconductor chip is at most 250 μm.

31. The method according to claim 30, wherein arranging the insert is carried out after arranging the optoelectronic semiconductor chip.

32. The method according to claim 30, wherein each cavity has a lateral extent of at least 250 μm.

33. The method according to claim 30, wherein the insert is arranged in contact with the side surface and the insert aligns at the side surface.

34. An optoelectronic semiconductor device comprising:
an optoelectronic semiconductor chip arranged in at least one cavity of a housing and configured to emit electromagnetic radiation; and
an insert,
wherein the cavity comprises at least one side surface at least partially laterally surrounding the optoelectronic semiconductor chip, and
wherein the insert is arranged between the optoelectronic semiconductor chip and the side surface at a distance from the optoelectronic semiconductor chip.
